(19) United States
(12) Patent Application Publication
(10) Pub. No.: US 2022/0301888 A1
(43) Pub. Date: Sep. 22, 2022

(54) PACKAGE SUBSTRATE STRUCTURE AND METHOD FOR MANUFACTURING SAME

(71) Applicant: MONTAGE TECHNOLOGY CO., LTD., Shanghai (CN)

(72) Inventors: Meng MEI, Shanghai (CN); Gang SHI, Shanghai (CN); Peichun WANG, Shanghai (CN); Guangfeng LI, Shanghai (CN)

(73) Assignee: MONTAGE TECHNOLOGY CO., LTD., Shanghai (CN)

(21) Appl. No.: 17/458,238

(22) Filed: Aug. 26, 2021

(30) Foreign Application Priority Data
Mar. 18, 2021 (CN) 2021102918588

(51) Int. Cl. H01L 21/48; H01L 23/498

(52) U.S. Cl. CPC H01L 21/486; H01L 23/49822; H01L 23/49827

(57) ABSTRACT

The present disclosure provides a package substrate structure and a method for manufacturing the same. The method includes: providing a substrate, forming a first hole with a first radial dimension in the substrate; forming a first metal layer on the sidewall of the first via to form a first via; filing the first via with a dielectric layer; forming a second hole with a second radial dimension in the dielectric layer, wherein the second radial dimension is smaller than the first radial dimension, and the second hole and the first metal layer are separated by the dielectric layer; filling the second hole with the second metal layer to form a second via. The high-speed circuit via design achieved by a sleeve via arrangement of the present disclosure can reduce the influence of the impedance mismatch caused by vias on insertion loss and the return loss in a specific frequency band.

### CROSS REFERENCE TO RELATED APPLICATION

The present application claims the benefit of priority to Chinese Patent Application No. CN 2021102918588, entitled “PACKAGE SUBSTRATE STRUCTURE AND METHOD FOR MANUFACTURING SAME”, filed with CNIPA on Mar. 18, 2021, the disclosure of which is incorporated herein by reference in its entirety.

### FIELD OF TECHNOLOGY

The present disclosure generally relates to the field of chip packaging, in particular, to a package substrate structure and a method for manufacturing the same.

### BACKGROUND

A package substrate is an important component of a chip package body, which mainly plays the role of carrying and protecting a chip and connecting the chip and a printed circuit board.

A complete chip is composed of a bare chip (wafer) and a package (package substrate, solid sealing material, leads, etc.). As a core component of chip packaging, on the one hand, the package substrate can protect, fix, and support the chip and can enhance the heat conduction and heat dissipation of the chip, to ensure that the chip is not physically damaged. On the other hand, the upper layer of the package substrate is connected to the chip, and the lower layer of the package substrate is connected to the printed circuit board, in order to realize the functions of electrical and physical connection, power distribution, signal distribution, and connecting the internal and external circuits of the chip.

As electronic chips are getting smaller and their data processing speed is getting faster and faster, the package substrate must transmit more and faster data signals in a smaller space without degrading the quality of the signals. High-density, high-speed substrates that can meet the aforementioned requirements are appearing in the industry. When designing a high-speed substrate, by adding a reference ground or power via next to a high-speed signal via to form an electric field loop, the integrity of high-speed signals can be effectively optimized. In such design, the distance between the high-speed signal via and the reference sleeve via and the number of the reference sleeve via(s) are usually adjusted to achieve impedance matching and reduce insertion loss and return loss. However, for this kind of structure, it is difficult to achieve full-band impedance matching, thereby resulting in a standing wave in the entire electric field loop. At the same time, the energy of the electromagnetic field will not only travel along the reference path, but will also diffuse in the medium, which will increase crosstalk between high-speed signals.

### SUMMARY

An objective of the present disclosure provides a package substrate structure and a method for manufacturing the same to solve the problem of serious crosstalk between high-speed signals in a high-speed substrate in the prior art.

In one aspect of the present disclosure a method for manufacturing a package substrate structure is provided. The method includes: providing a substrate, and forming a first hole with a first radial dimension in the substrate; forming a first metal layer on the sidewall of the first hole, so that a first via is produced; filling the first via with a dielectric layer; forming a second hole with a second radial dimension in the dielectric layer, wherein the second radial dimension is smaller than the first radial dimension, and the dielectric layer separates the second hole and the first metal layer; and filing the second hole with a second metal layer, so that a second via is produced.

In some embodiments, the substrate includes a first surface and a second surface opposite to each other, a reference layer is formed above the first surface and/or the second surface, the first metal layer is connected to the reference layer, and the reference layer is connected to a power source or a ground.

In some embodiments, the first hole in the substrate is formed by mechanical drilling; and the second hole in the dielectric layer is formed by laser drilling.

In some embodiments, the first radial dimension of the first hole is between 75 microns and 5000 microns, the second radial dimension of the second hole is between 45 microns and 100 microns, and the difference between the first radial dimension of the first hole and the second radial dimension of the second hole is greater than or equal to 40 microns.

In some embodiments, the material of the dielectric layer includes resin ink, and the filling the first via with the dielectric layer includes: filling the first via with resin ink by printing; curing the resin ink; flattening the resin ink by sandblasting.

In some embodiments, filing the second hole with the second metal layer includes: forming the second metal layer in the second hole with the second metal layer by electroplating; removing the second metal layer between the second hole and the first metal layer by a photo-lithography process and an etching process, to achieve electrical isolation between the second metal layer and the first metal layer.

In some embodiments, the method further includes: forming a signal layer above the substrate, with the second metal layer connected to the signal layer.

In some embodiments, the second metal layer is connected to the signal layer by means of stacked vias, which includes: forming an insulating layer on a surface of the substrate; forming a through hole in the insulating layer, the through hole exposing the second metal layer; forming a conductive plug in the through hole; and forming a signal metal layer above the insulating layer, the signal metal layer being electrically connected to the conductive plug.

In some embodiments, the materials of the first metal layer and the second metal layer are both copper.

In another aspect of the present disclosure, a package substrate structure is provided. The package substrate structure includes: a substrate, including a first hole with a first radial dimension; a first metal layer on the sidewall of the first hole to form a first via; a dielectric layer, filled in the first via, wherein a second hole with a second radial dimension is formed in the dielectric layer, wherein the second radial dimension is smaller than the first radial dimension, and the dielectric layer separates the second hole and the first metal layer; and a second metal layer, filled in the second hole to form a second via and electrically isolated from the first metal layer.

In some embodiments, the substrate includes a first surface and a second surface opposite to each other, a reference layer is formed above the first surface and/or the second surface, the first metal layer is connected to the reference layer, and the reference layer is connected to a power source or a ground

In some embodiments, the first radial dimension of the first hole is between 75 microns and 5000 microns, the second radial dimension of the second hole is between 45 microns and 100 microns, and the difference between the first radial dimension of the first hole and the second radial dimension of the second hole is greater than or equal to 40 microns.

In some embodiments, the material of the dielectric layer includes resin ink, and the materials of the first metal layer and the second metal layer are both copper.

In some embodiments, the substrate further includes a signal layer, and the signal layer is connected to the second metal layer by means of stacked vias.

In some embodiments, the insulating layer includes: an insulating layer formed above a surface of the substrate, wherein the insulating layer includes a through hole, the through hole exposes the second metal layer, and a conductive plug is filled in the through hole; and a signal metal layer, formed above the insulating layer, the signal metal layer being electrically connected to the conductive plug.

The above is an overview of the application, which may be simplified, summarized and omitted in detail. Therefore, those skilled in the art should realize that this part is only illustrative and is not intended to limit the scope of the application in any way. This summary section is neither intended to determine the key features or essential features of the claimed subject matter, nor is it intended to be used as an auxiliary means to determine the scope of the claimed subject matter.

### BRIEF DESCRIPTION OF THE DRAWINGS

FIGS. 1-12 show a package substrate structure and intermediate structures at various steps of the method for manufacturing the same according to an embodiment of the present disclosure.

FIG. 13 is a schematic diagram showing an exemplary package structure according to the present disclosure, which includes a package substrate structure with a sleeve via and a traditional single-hole according to the present disclosure.

FIG. 14 is a schematic diagram showing the cross-sectional structure at A-A′ in FIG. 13.

FIG. 15 is a schematic diagram showing the cross-sectional structure at B-B′ in FIG. 13.

FIG. 16 shows an insertion loss test curve of the package substrate structure of FIG. 13.

FIG. 17 shows a return loss test curve of the package substrate structure of FIG. 13.

FIG. 18 is a diagram showing the result of an electric field distribution test of the package substrate structure of FIG. 13.

### DETAILED DESCRIPTION

The following describes the implementation of the present disclosure through specific examples, and those skilled in the art can easily understand other advantages and effects of the present disclosure from the content disclosed in this specification. The present disclosure can also be implemented or applied through other different specific embodiments. Various details in this specification can also be modified or changed based on different viewpoints and applications without departing from the spirit of the present disclosure.

For example, when the embodiments of the present disclosure are described in detail, for ease of description, the cross-sectional view showing the device structure will not be partially enlarged according to the general scale, and the schematic diagram is only an example, which should not limit the scope of protection. In addition, the three-dimensional dimensions of length, width and depth should be included in the actual production.

For the convenience of description, spatial relation terms such as “below”, “under”, “beneath”, “on”, “above”, “up”, etc. may be used herein to describe the relationships between an element or feature and other elements or features. It will be understood that these spatial relationship terms are intended to encompass directions/orientations of the device in use or operation other than those depicted in the drawings. In addition, when a layer is referred to as being “between” two layers, it may be the only layer between the two layers, or one or more intervening layers may also be present.

In the context of the present application, a described structure in which a first feature is “above” a second feature may include an embodiment in which the first and second features are formed in direct contact, or may include embodiments in which other features formed between the first and second features so that the first and second features may not be in direct contact.

It should be noted that the drawings provided in this disclosure only illustrate the basic concept of the present disclosure in a schematic way, so the drawings only show the components related to the present disclosure. The drawings are not necessarily drawn according to the number, shape and size of the components in actual implementation; during the actual implementation, the type, quantity and proportion of each component may be changed as needed, and the components' layout may also be more complicated.

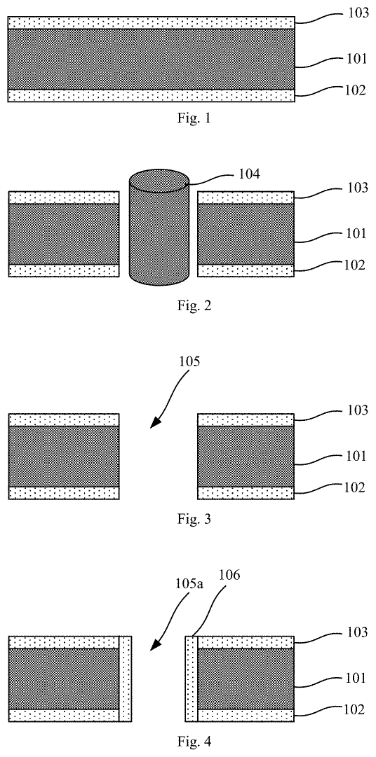

As shown in FIGS. 1-12, the present disclosure provides a package substrate structure and a method for manufacturing the same. The method includes:

As shown in FIGS. 1-3, step 1): providing a substrate 101, and forming a first hole 105 with a first radial dimension in the substrate 101;

The substrate 101 may be a rigid substrate or a flexible substrate. The material of the substrate 101 may be phenolic resin, epoxy resin, polyester resin, etc., and glass fiber cloth, polyamide fiber, and non-woven fabric may also be added to the above resin as a reinforcing material, to form a substrate with corresponding functions.

As shown in FIG. 1, the substrate 101 may include a first surface and a second surface opposite to each other. A first reference layer 102 and a second reference layer 103 are formed above the first surface and/or the second surface respectively. The reference layer 102 and the second reference layer 103 are connected to a power supply or ground. For example, the material of the first reference layer 102 and the second reference layer 103 may be copper.

As shown in FIGS. 2 and 3, in this disclosure, the first hole 105 is formed in the substrate 101 by mechanical drilling. In particular, a mechanical force is applied to the substrate 101 through a drill 104, so that the first hole 105 is formed in the substrate 101. The size of the first hole 105 formed by mechanical drilling is highly controllable, and the first hole 105 can be formed at low cost. In this disclosure, the radial dimension of the first hole 105 is between 75 microns and 5000 microns, such as 100 microns, 150 microns, 200 microns, etc., and the size of the drill 104 may be selected as needed. After the mechanical drilling is performed, a process such as nitrogen blowing may be used to clean the first hole 105 to remove residues adhering to a sidewall of the first hole 105 resulted from the mechanical drilling, to obtain a smooth sidewall surface.

As shown in FIG. 4, step 2) is then performed. In step 2), a first metal layer 106 is formed on the sidewalls of the first hole 105, so that a first via 105a is produced.

For example, a process such as electroplating may be used to form the first metal layer 106 on the sidewall of the first hole 105. The first metal layer 106 may be ring shaped. Specifically, a sputtering process may be used first to form a seed layer on the sidewall of the first hole 105 and the seed layer may include, for example, copper, or a stack of titanium and copper, to facilitate a subsequent electroplating process. Then, the electroplating process is used to form the first metal layer 106 on the seed layer. The first metal layer 106 is connected to a reference layer on the surface of the substrate 101, and the reference layer may be subsequently connected to a power supply or ground. In one embodiment, the material of the first metal layer 106 is copper.

As shown in FIG. 5 to FIG. 6, step 3) is performed: filling the first via 105a with a dielectric layer 107.

In one embodiment, the material of the dielectric layer 107 includes resin ink; and filling the first via 105a with the dielectric layer 107 may further include the following steps.

As shown in FIG. 5, step 3-1) is first performed. In step 3-1) resin ink is filled in the first via 105a by printing.

Then proceed to step 3-2): curing the resin ink. For example, for different resin inks, ultraviolet curing or thermal curing may be used.

As shown in FIG. 6, proceed to step 3-3): flattening the resin ink by sandblasting, to facilitate a subsequent drilling process in the dielectric layer 107.

As shown in FIG. 7, step 4) is then performed: forming a second hole 108 with a second radial dimension in the dielectric layer 107, with the second radial dimension smaller than the first radial dimension, and the second hole 108 separated from the first metal layer 106 by the dielectric layer 107.

In one embodiment, the second hole 108 is formed in the dielectric layer 107 by means of laser drilling. Forming the second hole 108 by means of laser drilling allows obtaining the hole with a smaller radial dimension in a relatively narrow space. At the same time, laser drilling can be accurately positioned without causing compression damage to the substrate 101. Especially for the second hole 108 formed in the dielectric layer 107, laser drilling can effectively avoid possible damages to the dielectric layer 107 during drilling and can avoid the risk of the dielectric layer 107 falling off due to compression. The radial dimension of the second hole 108 is between 45 microns and 100 microns, and the difference between the radial dimension of the first hole 105 and the radial dimension of the second hole 108 is greater than or equal to 40 micrometers. Specifically, the radial dimension of the second hole 108 may be, for example, 50 micrometers, 100 micrometers, 150 micrometers, or the like. Axes of the first and second holes may be on a same straight line. After laser drilling is performed, a process such as nitrogen blowing may be used to clean the first hole 108 to remove residues adhering to the sidewall of the first hole 108 resulted from the laser drilling process to obtain a smooth side wall surface.

As shown in FIGS. 8 to 11, then step 5) is performed to fill the second hole 108 with a second metal layer 109 to form a second via 108a. For example, the material of the second metal layer 109 may be copper.

Specifically, filling the second hole 108 with the second metal layer 109 may include the following steps.

As shown in FIG. 8, step 5-1) is first performed, and the second metal layer 109 is formed in the second hole 108 by electroplating. For example, a sputtering process may be used to form a seed layer on the sidewall of the second hole 108. The seed layer may include, for example, copper, or a stack of titanium and copper, to facilitate the subsequent electroplating process. Then, the second metal layer 109 is formed on the seed layer by an electroplating process. The second hole 108 is filled with the second metal layer 109 to improve the mechanical strength of the structure and the signal transmission capability of the second metal layer 109. It should be noted that when the second metal layer 109 is formed in the second hole 108 through an electroplating process, the second metal layer 109 is also be formed above the first surface and the second surface of the substrate 101 at the same time, as shown in FIG. 8.

As shown in FIGS. 9 to 11, step 5-2) is then performed to remove the second metal layer 109 between the second hole 108 and the first metal layer 106 (i.e., the portion of the second metal layer 109 above and/or below the dielectric layer 107) through a photo-lithography process and an etching process in order to achieve electrical isolation between the second metal layer 109 and the first metal layer 106.

Specifically, step 5-2) includes the following steps.

As shown in FIG. 9, step 5-2a) is performed to form a mask pattern 110 (such as photoresist or other hard mask) above the substrate 101, and the mask pattern 110 has a window exposing a portion of the second metal layer 109.

As shown in FIG. 10, step 5-2b) is performed to use a wet etching or dry etching process to remove the second metal layer 109 between the second hole 108 and the first metal layer 106 to achieve electrical isolation between the second metal layer 109 and the first metal layer 106.

As shown in FIG. 11, step 5-2c) is performed to remove the mask pattern 110 and clean the substrate 101.

As shown in FIG. 12, in one embodiment, the method may further include step 6): forming a signal layer above the substrate 101, with the second metal layer 109 electrically connected to the signal layer.

Specifically, the second metal layer 109 is connected to the signal layer by means of stacked vias, which comprises:

Step 6-1), forming an insulating layer 201 above the surface of the substrate 101, wherein the insulating layer 201 may include for example, polyimide or resin ink.

Step 6-2), forming a through hole in the insulating layer 201, with the through hole exposing the second metal layer 109.

Step 6-3), forming a conductive plug 202 in the through hole; and

Step 6-4), forming a signal metal layer 203 on the insulating layer 201, with the signal metal layer 203 electrically connected to the conductive plug 202.

It should be noted that in another embodiment, the first hole may be formed by mechanical drilling, and the second hole may be formed by mechanical drilling; in yet another embodiment, the first hole may be formed by laser drilling, and the second hole may be formed by laser drilling. In yet another embodiment, a via structure (hereafter referred to as “sleeve via structure”) in which a large hole is sleeved with a middle hole and a small hole is sleeved in the middle hole may also be formed. Axes of the holes may be on a same straight line. Furthermore, a sleeve via structure with more layers may also be formed. In yet another embodiment, it is also possible to form two or more independent small holes in a large hole, such as forming a differential line with the two independent small holes. The above-mentioned embodiments should be included in the scope of the present disclosure.

As shown in FIG. 11, this disclosure also provides a package substrate structure. The package substrate structure includes: a substrate 101 in which a first hole 105 with a first radial dimension is formed; a first metal layer 106, located on the sidewall of the first hole 105 to form a first via 105a; a dielectric layer 107, filled in the first via 105a, wherein a second hole 108 with a second radial dimension is formed in the dielectric layer 107, wherein the second radial dimension is smaller than the first radial dimension, and the second hole 108 and the first metal layer 106 are separated by the dielectric layer 107; and a second metal layer 109, filled in the second hole 108 to form a second via 108a and electrically isolated from the first metal layer 106.

The substrate 101 may be a rigid substrate or a flexible substrate. The material of the substrate 101 may be phenolic resin, epoxy resin, polyester resin, etc., and glass fiber cloth, polyamide fiber, and non-woven fabric may also be added to the above resin as a reinforcing material, to form a substrate with corresponding functions. The substrate 101 includes a first surface and a second surface opposite to each other. A reference layer is formed on the first surface and/or the second surface, the first metal layer is connected to the reference layer, and the reference layer is connected to a power source or a ground. The reference layer may include copper.

The radial dimension of the first hole 105 is between 75 microns and 5000 microns, for example, 100 microns, 150 microns, 200 microns, etc., and the radial dimension of the second hole 108 is between 45 microns and 100 microns, for example, 50 micrometers, 100 micrometers, 150 micrometers, etc., and the difference between the radial dimension of the first hole 105 and the radial dimension of the second hole 108 is greater than or equal to 40 microns.

The material of the dielectric layer 107 may include resin ink, and the materials of the first metal layer 106 and the second metal layer 109 may be both copper.

As shown in FIG. 12, the substrate 101 further includes a signal layer, and the signal layer is connected to the second metal layer 109 by means of stacked vias. Specifically, the signal layer may include: an insulating layer 201 formed above the surface of the substrate 101, wherein the insulating layer 201 has a through hole exposing a portion of the second metal layer 109 and filled with a conductive plug 202; and a signal metal layer 203 formed on the insulating layer 201, wherein the signal metal layer 203 is electrically connected to the conductive plug 202.

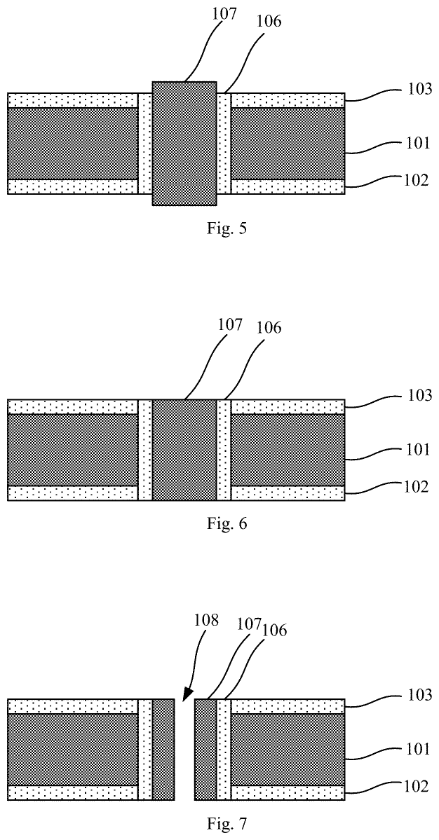

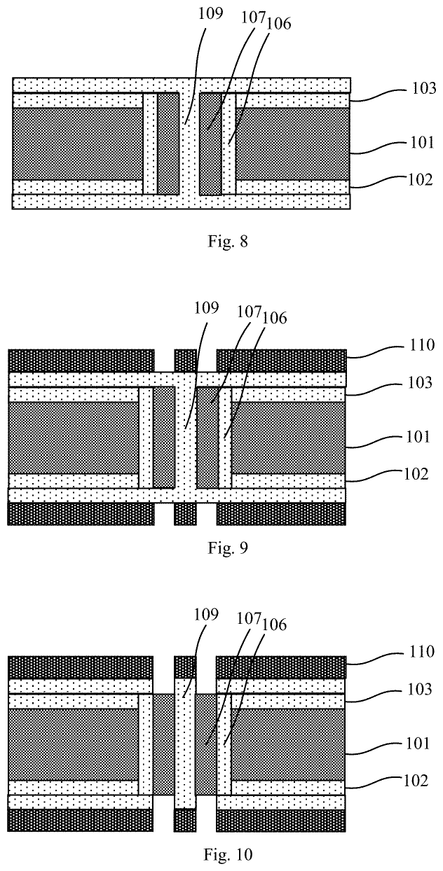

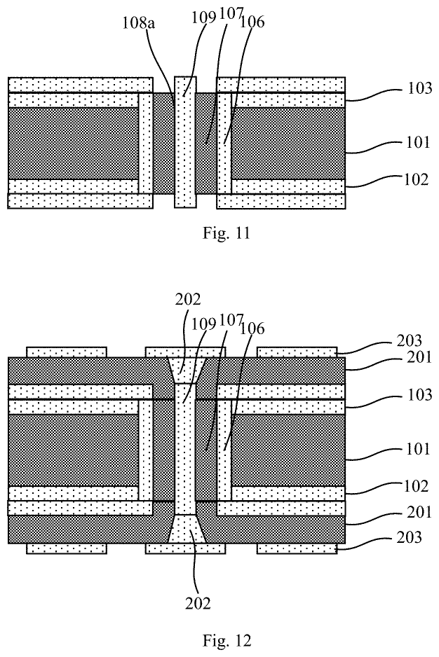

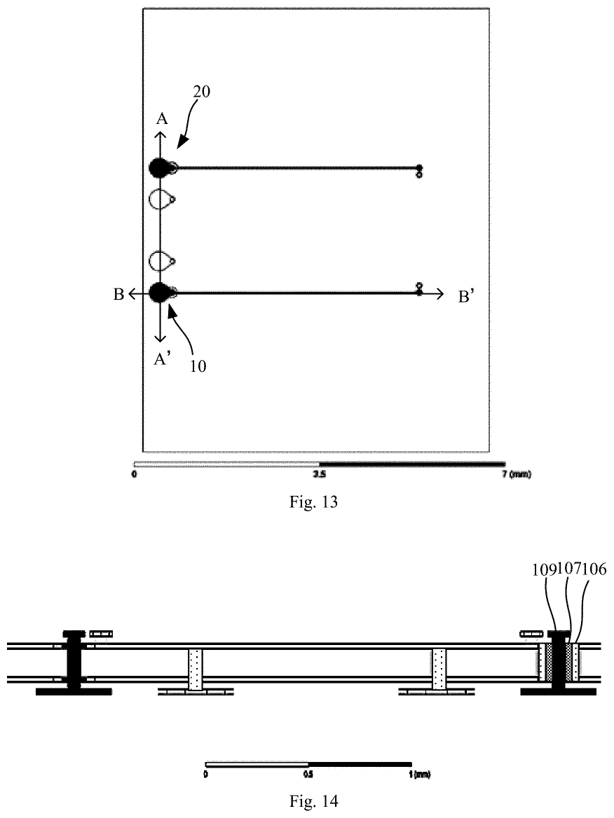

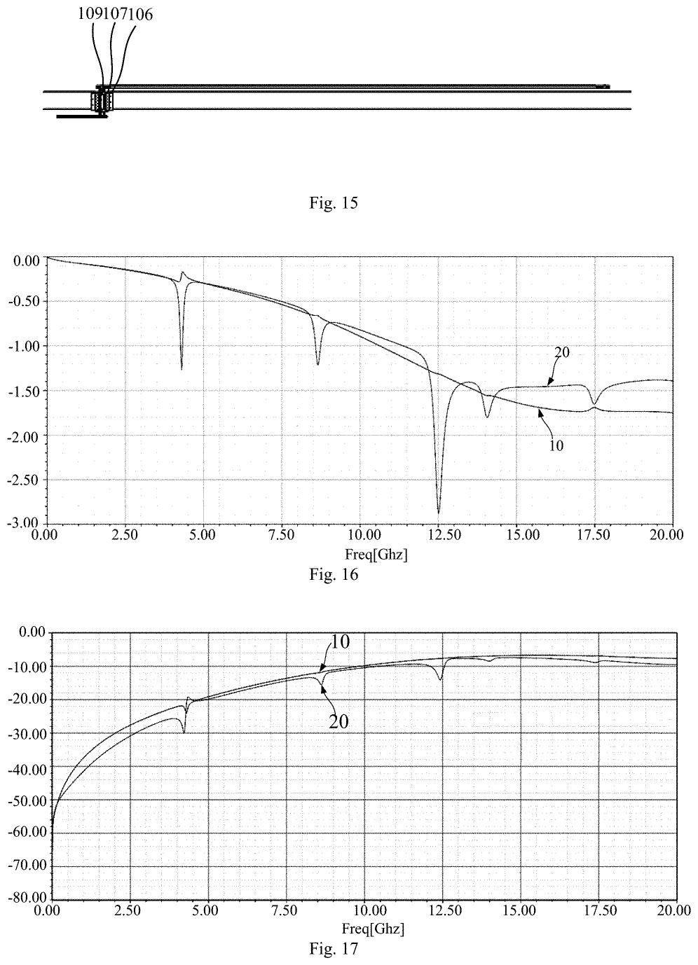

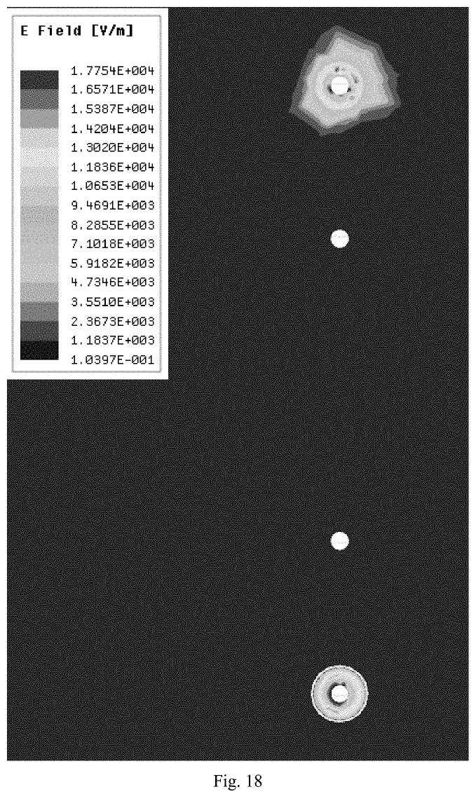

FIG. 13 is a schematic diagram showing an exemplary package structure according to the present disclosure, which includes a package substrate structure with a sleeve via arrangement 10 and a traditional single-hole arrangement design 20 according to the present disclosure. FIG. 14 is a schematic diagram showing the cross-sectional structure at A-A′ in FIG. 13. FIG. 15 is a schematic diagram showing the cross-sectional structure at B-B′ in FIG. 13. In one embodiment, the insertion loss test, return loss test, and electric field distribution test are performed on the package substrate structure in FIG. 13 which has the traditional single hole arrangement 20 and the sleeve via arrangement 10 of the present disclosure. Among them, the insertion loss test curve is shown in FIG. 16, the return loss test curve is shown in FIG. 17, and the electric field distribution is shown in FIG. 18. As shown in FIGS. 16-18, the high-speed circuit via design achieved by the method of the present disclosure can reduce the influence of impedance mismatch caused by vias on insertion loss and return loss in a specific frequency band, as shown in FIGS. 16-17. At the same time, via energy of high-speed signals is also limited in the dielectric layer 107 in the middle of a sleeve via, which can reduce the crosstalk of the high-speed signals, as shown in FIG. 18.

As mentioned above, in the present disclosure, by first mechanically drilling and forming a hole with a relatively large radial dimension based on required high-speed signals, and then superimposing laser drilling upon the mechanical drilling to form a hole with a relatively small radial dimension, signal line vias are formed as sleeve vias; the vias with larger radial dimensions are directly connected to the reference layer, such as the power supply or ground, and the vias with smaller radial dimensions are connected to a signal routing layer by means of stacking holes. By forming a structure similar to a coaxial line in the area where mechanical drilling and laser drilling are performed, impedance matching is achieved, thereby reducing insertion loss and return loss and constraining the electric field energy of high-speed signals to the dielectric layer 107 between the holes formed by the laser drilling and mechanical drilling. The high-speed circuit via design achieved by the method of the present disclosure can reduce the influence of impedance mismatch caused by vias on insertion loss and return loss in a specific frequency band. Meanwhile, via energy of high-speed signals is also limited in the dielectric layer 107 in the middle of a sleeve via, which can reduce the crosstalk of the high-speed signals.

Therefore, the present disclosure effectively overcomes various shortcomings in the prior art and has a high industrial value.

The above-mentioned embodiments only exemplarily illustrate the principles and effects of the present disclosure, but are not used to limit the present disclosure. Anyone familiar with this technology may modify or change the above-mentioned embodiments without departing from the spirit and scope of the present disclosure. Therefore, all equivalent modifications or changes made by those skilled in the art without departing from the spirit and technical concepts disclosed by the present disclosure should still be covered by the attached claims of the present disclosure.

What is claimed is:

1, A method for manufacturing a package substrate structure, comprising:
providing a substrate;
forming a first hole with a first radial dimension in the substrate;
forming a first metal layer on the sidewall of the first hole, so that a first via is produced;
filling the first via with a dielectric layer;
forming a second hole with a second radial dimension in the dielectric layer, wherein the second radial dimension is smaller than the first radial dimension, and the second hole and the first metal layer are separated by the dielectric layer; and
filing the second hole with a second metal layer, so that a second via is produced.

2, The method for manufacturing a package substrate structure according to claim 1, wherein the substrate comprises a first surface and a second surface opposite to each other, a reference layer is formed above the first surface and/or the second surface, the first metal layer is connected to the reference layer, and the reference layer is connected to a power source or ground.

3, The method for manufacturing a package substrate structure according to claim 1, further comprising: forming the first hole in the substrate by mechanical drilling; and forming the second hole in the dielectric layer by laser drilling.

4, The method for manufacturing a package substrate structure according to claim 1, wherein the first radial dimension of the first hole is between 75 microns and 5000 microns, the second radial dimension of the second hole is between 45 microns and 100 microns, and the difference between the first radial dimension of the first hole and the second radial dimension of the second hole is greater than or equal to 40 microns.

5, The method for manufacturing a package substrate structure according to claim 1, wherein the material of the dielectric layer includes resin ink, and the filling the first via with the dielectric layer comprises:
filling the first via with resin ink by printing;
curing the resin ink; and
flattening the resin ink by sandblasting.

6, The method for manufacturing a package substrate structure according to claim 1, wherein the filing the second hole with the second metal layer comprises:
forming the second metal layer in the second hole by electroplating; and
removing the second metal layer between the second hole and the first metal layer by a photo-lithography process and an etching process, to achieve electrical isolation between the second metal layer and the first metal layer.

7, The method for manufacturing a package substrate structure according to claim 1, further comprising: forming a signal layer above the substrate, wherein the second metal layer is connected to the signal layer by means of stacked vias.

8, The method for manufacturing a package substrate structure according to claim 7, wherein connecting the second metal layer to the signal layer by means of stacked vias comprises:
forming an insulating layer above the first surface and/or the second surface of the substrate;
forming a through hole in the insulating layer, wherein a portion of the second metal layer is exposed by the through hole;
forming a conductive plug in the through hole; and
forming a signal metal layer above the insulating layer, wherein the signal metal layer is electrically connected to the conductive plug.

9, The method for manufacturing a package substrate structure according to claim 1, wherein the materials of the first metal layer and the second metal layer are both copper.

10, A package substrate structure, comprising:
a substrate, comprising a first hole with a first radial dimension;
a first metal layer located on a sidewall of the first hole to form a first via;
a dielectric layer, filled in the first via, comprising a second hole with a second radial dimension, wherein the second radial dimension is smaller than the first radial dimension, and the dielectric layer separates the second hole and the first metal layer; and
a second metal layer, filled in the second hole and electrically isolated from the first metal layer to form a second via.

11, The package substrate structure according to claim 10, wherein the substrate comprises a first surface and a second surface opposite to each other, a reference layer is formed above the first surface and/or the second surface, the first metal layer is connected to the reference layer, and the reference layer is connected to a power source or ground

12, The package substrate structure according to claim 10, wherein the first radial dimension of the first hole is between 75 microns and 5000 microns, the second radial dimension of the second hole is between 45 microns and 100 microns, and the difference between the first radial dimension of the first hole and the second radial dimension of the second hole is greater than or equal to 40 microns.

13, The package substrate structure according to claim 10, wherein the material of the dielectric layer includes resin ink, and the materials of the first metal layer and the second metal layer are both copper.

14, The package substrate structure according to claim 10, further comprising a signal layer, wherein the signal layer is connected to the second metal layer by means of stacked vias.

15, The package substrate structure according to claim 14, wherein the signal layer comprises:
an insulating layer formed above a surface of the substrate, wherein the insulating layer includes a through hole, the through hole exposes the second metal layer, and a conductive plug is filled in the through hole; and
a signal metal layer, formed above the insulating layer, wherein the signal metal layer is electrically connected to the conductive plug.
